(19) United States
(12) Patent Application Publication
(10) Pub. No.: US 2026/0301783 A1
(43) Pub. Date: Oct. 1, 2026

(54) MEMORY DEVICE AND OPERATING METHOD OF THE SAME

(71) Applicant: SK hynix Inc., Gyeonggi-do (KR)

(72) Inventors: Hong Ki MOON, Gyeonggi-do (KR); Min Su PARK, Gyeonggi-do (KR)

(21) Appl. No.: 19/269,054

(22) Filed: Jul. 15, 2025

(30) Foreign Application Priority Data
Mar. 27, 2025 (KR) 10-2025-0039448

(51) Int. Cl. G11C 7/06; G11C 7/22; G11C 8/08

(52) U.S. Cl. CPC G11C 7/06; G11C 7/22; G11C 8/08

(57) ABSTRACT

An operating method of a memory device, includes receiving a row address that designates a first word line and an active command, enabling the first word line and activating a first bit line sense amplifier (BLSA) array corresponding to the first word line, receiving a row address that designates a second word line and the active command, and enabling the second word line and activating a second BLSA array corresponding to the second word line.

### CROSS-REFERENCE TO RELATED APPLICATION

This application claims priority under 35 U.S.C. § 119(a) to Korean Patent Application No. 10-2025-0039448, filed on Mar. 27, 2025, the entire contents of which are incorporated herein by reference.

### BACKGROUND

### 1. Technical Field

Embodiments of the present disclosure generally relate to an integrated circuit technology and, more particularly, to a memory device and an operating method of the same.

### 2. Related Art

Recently, as an electronic device is reduced in size, has lower power consumption and higher performance, and is diversified, a semiconductor device capable of storing information is required for various electronic devices, such as computers and portable communication devices. The semiconductor device may be basically divided into a volatile memory device and a nonvolatile memory device. The volatile memory device has a high data processing speed but has a disadvantage in that the volatile memory device needs to be continuously supplied with power to maintain data that has been stored in the volatile memory device. The nonvolatile memory device does not need to be continuously supplied with power to maintain data that has been stored in the nonvolatile memory device, but has a disadvantage in that the nonvolatile memory device has a low data processing speed.

A volatile memory device continues to be researched to reduce power consumption while increasing the data processing speed.

### SUMMARY

In an embodiment of the present disclosure, an operating method of a memory device may include receiving a row address that designates a first word line and an active command, enabling the first word line and activating a first bit line sense amplifier (BLSA) array corresponding to the first word line, receiving a row address that designates a second word line and the active command, and enabling the second word line and activating a second BLSA array corresponding to the second word line.

In an embodiment of the present disclosure, a memory device may include a plurality of data storage regions each including a plurality of memory cells, a plurality of bit line sense amplifier (BLSA) arrays configured to sense and amplify data of the plurality of data storage regions, respectively, and a RAS control circuit configured to disable one or more word lines enabled in the plurality of data storage regions in response to a word line precharge command and configured to deactivate one or more BLSA arrays activated, among the plurality of BLSA arrays, in response to a bit line precharge command.

In an embodiment of the present disclosure, a memory device may include a row decoder configured to enable a first word line by receiving a row address that designates the first word line and an active command and configured to enable a second word line by receiving a row address that designate a second word line and the active command and a RAS control circuit configured to activate a first bit line sense amplifier (BLSA) corresponding to the first word line based on the row address that designates the first word line and activate a second BLSA corresponding to the second word line based on the row address that designates the second word line.

### BRIEF DESCRIPTION OF THE DRAWINGS

FIG. 1 is a diagram for describing a memory system according to an embodiment of the present disclosure.

FIG. 2 is a diagram for describing a memory device according to an embodiment of the present disclosure.

FIGS. 3 to 5 are diagrams for describing operations of the memory device according to an embodiment of the present disclosure.

### DETAILED DESCRIPTION

Hereinafter, embodiments according to the technical spirit of the present disclosure are described with reference to the accompanying drawings.

Embodiments of the present disclosure provide a memory device capable of reducing a read operation time according to a continued read command and an operating method of the same.

It is possible to reduce a read operation time according to a continued read command and to reduce power consumption.

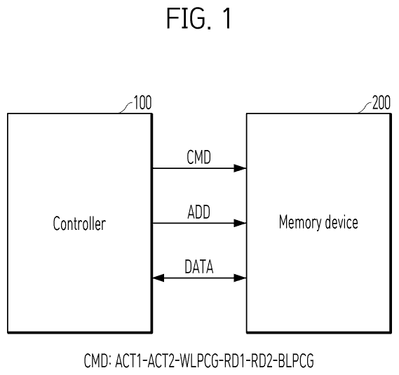

FIG. 1 is a diagram for describing a memory system according to an embodiment of the present disclosure.

Referring to FIG. 1, the memory system according to an embodiment of the present disclosure may include a controller 100 and a memory device 200.

The controller 100 may store data DATA in the memory device 200 or may receive data DATA stored in the memory device 200. For example, the controller 100 may store the data DATA in the memory device 200 by providing a command CMD, an address ADD and the data DATA to the memory device 200. In this case, the command CMD may include a write command.

The controller 100 may receive the data DATA stored in the memory device 200 by providing the command CMD and the address ADD to the memory device 200. In this case, the command CMD may include a read command.

Accordingly, the address ADD, together with the command CMD, may be received by the memory device 200.

The memory device 200 may be configured to store the data DATA or to output the data DATA stored in the memory device 200 to the controller 100 under the control of the controller 100.

The controller 100 of the memory system according to an embodiment of the present disclosure may provide a continued read command to the memory device 200. Furthermore, the memory device 200 may be configured to perform a continued read operation in response to a continued read command.

For example, a controller of a common memory system may sequentially provide a memory device with an active command, a read command, and a precharge command to control the memory device to perform a read operation. Accordingly, for the memory device to perform two read operations, the controller of the common memory system may transmit the active command, the read command, and the precharge command to the memory device, and may then provide the active command, the read command, and the precharge command to the memory device again.

In contrast, for the memory device 200 to perform two read operations, the controller 100 of the memory system according to an embodiment of the present disclosure may sequentially provide the memory device 200 with a first active command ACT1, a second active command ACT2, a word line precharge command WLPCG, a first read command RD1, a second read command RD2, and a bit line precharge command BLPCG.

The memory system that performs a continued read operation in order of such commands can reduce the read operation time of the memory device 200 according to the continued read command. The reason for this is that the time required for the memory device 200 to wait until the memory device 200 performs an active operation after performing a precharge operation is removed and the number of commands that need to be received by the memory device 200 from the controller 100 is reduced. For example, in common cases, to perform three read operations, the active command, the read command, and the precharge command need to be repeated three times. In contrast, in the memory system according to an embodiment of the present disclosure, three active commands, one word line precharge command, three read commands, and one bit line precharge command are required. That is, in common cases, to perform three read operations, nine commands need to be transmitted to the memory device. In contrast, in the memory system according to an embodiment of the present disclosure, a total of eight commands are transmitted to the memory device. In the memory system according to an embodiment of the present disclosure, as the number of continued read operations is increased, the number of commands that need to be received by the memory device 200 may be reduced.

The memory device 200 of the memory system according to an embodiment of the present disclosure may be configured to perform a bit line precharge operation after a continued read operation by separating a word line precharge operation from the bit line precharge operation. That is, the memory device 200 of the memory system according to an embodiment of the present disclosure may be configured to continuously activate different word lines, activate sense amplifiers corresponding to the activated word lines, respectively, and then output data sensed by each activated sense amplifier based on a continued read command.

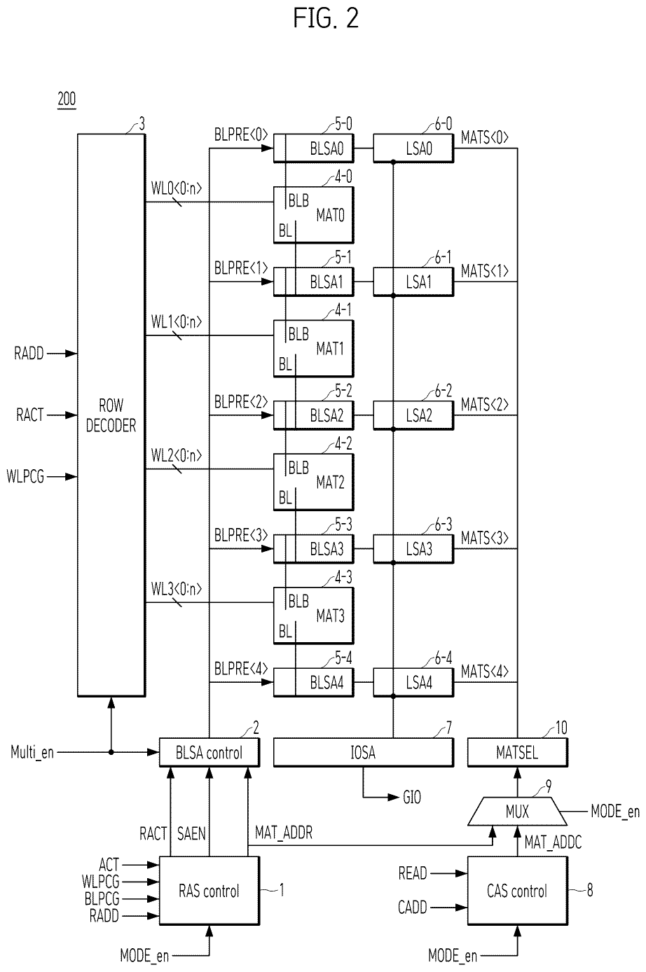

FIG. 2 is a diagram for describing a memory device according to an embodiment of the present disclosure.

Referring to FIG. 2, the memory device 200 according to an embodiment of the present disclosure may include a RAS control circuit 1, a bit line sense amplifier (BLSA) control circuit 2, a row decoder 3, first to fourth mats 4-0, 4-1, 4-2, and 4-3, first to fifth BLSA arrays (BLSA0, BLSA1, BLSA2, BLSA3, and BLSA4) 5-0, 5-1, 5-2, 5-3, and 5-4, first to fifth local sense amplifiers (LSAs) (LSA0, LSA1, LSA2, LSA3, and LSA4) 6-0, 6-1, 6-2, 6-3, and 6-4, an input and output sense amplifier (IOSA) 7, a CAS control circuit 8, an address selection circuit (MUX) 9, and a mat selection circuit (MATSEL) 10. In this case, the first to fourth mats 4-0, 4-1, 4-2, and 4-3 may be data storage regions included in the same bank and may be data storage regions included in different banks.

The RAS control circuit 1 may generate a row active signal RACT, a sense amplifier enable signal SAEN, and a first mat address MAT_ADDR, based on an active command ACT, the word line precharge command WLPCG, the bit line precharge command BLPCG, a row address RADD, and a mode enable signal MODE_en. In this case, the active command ACT may be a command that enables a word line. The word line precharge command WLPCG may be a command that disables an enabled word line. The row address RADD may be an address that selects an enabled word line. The mode enable signal MODE_en may be a signal that sets the timing at which a word line is disabled and the timing at which a bit line is precharged to be either the same or different. The row active signal RACT may be a signal that determines timing at which a word line is enabled and timing at which a word line is disabled. The sense amplifier enable signal SAEN may be a signal that determines timing at which a BLSA array is activated and timing at which a BLSA array is deactivated. For example, when the active command ACT is input, the RAS control circuit 1 may enable the row active signal RACT and the sense amplifier enable signal SAEN. When the word line precharge command WLPCG is input in the state in which the mode enable signal MODE_en has been disabled, the RAS control circuit 1 may disable both an enabled row active signal RACT and an enabled sense amplifier enable signal SAEN. When the word line precharge command WLPCG is input in the state in which the mode enable signal MODE_en has been enabled, the RAS control circuit 1 may disable only the row active signal RACT. Furthermore, when the bit line precharge command BLPCG is input in the state in which the mode enable signal MODE_en has been enabled, the RAS control circuit 1 may disable an enabled sense amplifier enable signal SAEN. Furthermore, the RAS control circuit 1 may generate the first mat address MAT_ADDR by decoding the row address RADD. In this case, the first mat address MAT_ADDR may include information with regard to a mat including an enabled word line.

The BLSA control circuit 2 may enable or disable at least one of first to fifth bit line precharge signals BLPRE<0>, BLPRE<1>, BLPRE<2>, BLPRE<3>, and BLPRE<4>, based on the row active signal RACT, the sense amplifier enable signal SAEN, a multi-enable signal Multi_en, and the first mat address MAT_ADDR. For example, when the sense amplifier enable signal SAEN is enabled in the state in which the multi-enable signal Multi_en has been disabled, the BLSA control circuit 2 may disable one bit line precharge signal corresponding to the first mat address MAT_ADDR, among the first to fifth bit line precharge signals BLPRE<0>, BLPRE<1>, BLPRE<2>, BLPRE<3>, and BLPRE<4>. When the sense amplifier enable signal SAEN is enabled in the state in which the multi-enable signal Multi_en has been enabled, the BLSA control circuit 2 may disable a plurality of bit line precharge signals corresponding to the first mat address MAT_ADDR, among the first to fifth bit line precharge signals BLPRE<0>, BLPRE<1>, BLPRE<2>, BLPRE<3>, and BLPRE<4>. Furthermore, when the sense amplifier enable signal SAEN is disabled, the BLSA control circuit 2 may enable at least one bit line precharge signal that has been disabled.

The row decoder 3 may select at least one word line group, among first to fourth word line groups WL0<0:n>, WL1<0:n>, WL2<0:n>, and WL3<0:n>, based on the row address RADD, the row active signal RACT, and the multi-enable signal Multi_en, and may enable at least one word line in the selected word line group. For example, when the row active signal RACT is enabled in the state in which the multi-enable signal Multi_en has been disabled, the row decoder 3 may select one word line group corresponding to the row address RADD, among the first to fourth word line groups WL0<0:n>, WL1<0:n>, WL2<0:n>, and WL3<0:n>, and may enable one word line included in the selected word line group. When the row active signal RACT is enabled in the state in which the multi-enable signal Multi_en has been enabled, the row decoder 3 may select a plurality of word line groups corresponding to the row address RADD, among the first to fourth word line groups WL0<0:n>, WL1<0:n>, WL2<0:n>, and WL3<0:n>, and may enable one word line included in each of the selected word line groups. In this case, each of the first to fourth word line groups WL0<0:n>, WL1<0:n>, WL2<0:n>, and WL3<0:n> may include a plurality of word lines. Furthermore, the row decoder 3 may disable at least one word line that has been enabled, based on the word line precharge signal WLPCG.

Each of the first to fourth mats 4-0, 4-1, 4-2, and 4-3 may include a plurality of memory cells that is connected between the plurality of word lines and the plurality of bit lines. The memory cell may be a component that stores data. Each of the first to fourth mats 4-0, 4-1, 4-2, and 4-3 may be a data storage region including a set number of memory cells. In this case, the plurality of bit lines may include a positive bit line BL and a negative bit line BLB. Furthermore, the first mat 4-0 may include a plurality of memory cells that is connected between the word lines of the first word line group WL0<0:n> and a plurality of bit lines BL and BLB. The second mat 4-1 may include a plurality of memory cells that is connected between the word lines of the second word line group WL1<0:n> and a plurality of bit lines BL and BLB. The third mat 4-2 may include a plurality of memory cells that is connected between the word lines of the third word line group WL2<0:n> and a plurality of bit lines BL and BLB. The fourth mat 4-3 may include a plurality of memory cells that is connected between the word lines of the fourth word line group WL3<0:n> and a plurality of bit lines BL and BLB.

Each of the first to fifth BLSA arrays 5-0, 5-1, 5-2, 5-3, and 5-4 may be activated when a corresponding bit line precharge signal, among the first to fifth bit line precharge signals BLPRE<0>, BLPRE<1>, BLPRE<2>, BLPRE<3>, and BLPRE<4>, is disabled. The activated BLSA array may sense and amplify a difference between the voltage levels of the positive bit line BL and the negative bit line BLB. Furthermore, each of the first to fifth BLSA arrays 5-0, 5-1, 5-2, 5-3, and 5-4 may latch the sensed and amplified value until a corresponding bit line precharge signal, among the first to fifth bit line precharge signals BLPRE<0>, BLPRE<1>, BLPRE<2>, BLPRE<3>, and BLPRE<4>, is enabled. For example, the first BLSA array BLSA0 5-0 may be electrically connected to a positive bit line (not illustrated) and the negative bit line BLB included in the first mat MAT0. The second BLSA array BLSA1 5-1 may be electrically connected to the positive bit line BL included in the first mat MAT0 and the negative bit line BLB included in the second mat MAT1. The third BLSA array BLSA2 5-2 may be electrically connected to the positive bit line BL included in the second mat MAT1 and the negative bit line BLB included in the third mat MAT2. The fourth BLSA array BLSA3 5-3 may be electrically connected to the positive bit line BL included in the third mat MAT2 and the negative bit line BLB included in the fourth mat MAT3. The fifth BLSA array BLSA4 5-4 may be electrically connected to the positive bit line BL included in the fourth mat MAT3 and a negative bit line (not illustrated). In this case, each of the first to fifth BLSA arrays 5-0, 5-1, 5-2, 5-3, and 5-4 may include a plurality of bit lines sense amplifiers. Furthermore, in this specification, the expression that a BLSA array has been activated may include a meaning that a BLSA included in the BLSA array has been activated.

Each of the first to fifth LSAs 6-0, 6-1, 6-2, 6-3, and 6-4 may be activated when a corresponding mat selection signal, among the first to fifth mat selection signals MATS<0>, MATS<1>, MATS<2>, MATS<3>, and MATS<4>, is enabled. The first LSA 6-0 may be activated when the first mat selection signal MATS<0> is enabled, and may transmit the latch value of the first BLSA array 5-0 to the IOSA 7 by sensing and amplifying the latch value. The second LSA 6-1 may be activated when the second mat selection signal MATS<1> is enabled, and may transmit the latch value of the second BLSA array 5-1 to the IOSA 7 by sensing and amplifying the latch value. The third LSA 6-2 may be activated when the third mat selection signal MATS<2> is enabled, and may transmit the latch value of the third BLSA array 5-2 to the IOSA 7 by sensing and amplifying the latch value. The fourth LSA 6-3 may be activated when the fourth mat selection signal MATS<3> is enabled, and may transmit the latch value of the fourth BLSA array 5-3 to the IOSA 7 by sensing and amplifying the latch value. The fifth LSA 6-4 may be activated when the fifth mat selection signal MATS<4> is enabled, and may transmit the latch value of the fifth BLSA array 5-4 to the IOSA 7 by sensing and amplifying the latch value.

The IOSA 7 may transmit the values transmitted by the first to fifth LSAs 6-0, 6-1, 6-2, 6-3, and 6-4, respectively, to a global input and output line GIO as data. Data output by the global input and output line GIO may be transmitted to the controller 100 through a data input and output pad (not illustrated).

The CAS control circuit 8 may generate a second mat address MAT_ADDC based on the mode enable signal MODE_en, a read command READ, and a column address CADD. For example, when the mode enable signal MODE_en is disabled, the CAS control circuit 8 may stop the generation of the second mat address MAT_ADDC according to the read command READ and the column address CADD. When the read command READ is received in the state in which the mode enable signal MODE_en has been enabled, the CAS control circuit 8 may generate the second mat address MAT_ADDC according to the column address CADD.

The address selection circuit 9 may select one of the first mat address MAT_ADDR and the second mat address MAT_ADDC based on the mode enable signal MODE_en, and may provide the selected mat address to the mat selection circuit 10. The address selection circuit 9 may include a multiplexer. For example, when the mode enable signal MODE_en is disabled, the address selection circuit 9 may provide the first mat address MAT_ADDR, among the first and second mat addresses MAT_ADDR and MAT_ADDC, to the mat selection circuit 10. When the mode enable signal MODE_en is enabled, the address selection circuit 9 may provide the second mat address MAT_ADDC, among the first and second mat selection signals MAT_ADDR and MAT_ADDC, to the mat selection circuit 10.

The mat selection circuit 10 may enable one of the first to fifth mat selection signals MATS<0>, MATS<1>, MATS<2>, MATS<3>, and MATS<4> based on the output of the address selection circuit 9. In this case, the address ADD illustrated in FIG. 1 may include the row address RADD and the column address CADD illustrated in FIG. 2. Furthermore, as described above, the first mat address MAT_ADDR may be an address that is generated based on the row address RADD. The second mat address MAT_ADDC may be an address that is generated based on the column address CADD.

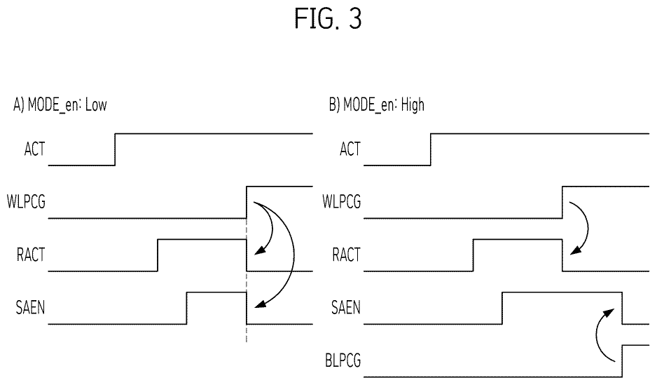

Operations of the memory device of the memory system constructed as described above according to embodiments of the present disclosure are described as follows with reference to FIGS. 3 to 5.

FIGS. 3 to 5 are diagrams for describing operations of the memory device according to an embodiment of the present disclosure.

FIG. 3 is a timing diagram for describing an operation of the RAS control circuit 1 illustrated in FIG. 2. In the timing diagrams illustrated in A) and B) of FIG. 3, the levels of commands and signals are indicated as a high level and a low level, but are merely one embodiment and the levels of the commands and the signals are not limited.

A) of FIG. 3 may illustrate the timing diagram of the RAS control circuit 1 in the state in which the mode enable signal MODE_en has been disabled. In this case, the mode enable signal MODE_en is in the state in which the mode enable signal MODE_en has been disabled at a low level.

Referring to A) of FIG. 3, the active command ACT may be received by the RAS control circuit 1. That is, the level of the active command ACT may be changed from a low level to a high level. When receiving the active command ACT having the level changed into the high level, the RAS control circuit 1 may change the level of the row active signal RACT from a low level to a high level. After changing the level of the row active signal RACT into the high level, the RAS control circuit 1 may change the level of the sense amplifier enable signal SAEN from a low level to a high level. When receiving the word line precharge command WLPCG having a level changed from a low level to a high level, the RAS control circuit 1 may change both the levels of the row active signal RACT and the sense amplifier enable signal SAEN to a low level.

As a result, when receiving the active command ACT in the state in which the mode enable signal MODE_en has been disabled, the RAS control circuit 1 may sequentially enable the row active signal RACT and the sense amplifier enable signal SAEN. Furthermore, when receiving the word line precharge command WLPCG, the RAS control circuit 1 may disable both the row active signal RACT and the sense amplifier enable signal SAEN that have been enabled.

B) of FIG. 3 may illustrate the timing diagram of the RAS control circuit 1 in the state in which the mode enable signal MODE_en has been enabled. In this case, the mode enable signal MODE_en is in the state in which the mode enable signal MODE_en has been enabled to a high level.

Referring to B) of FIG. 3, the active command ACT may be received by the RAS control circuit 1. That is, the level of the active command ACT may be changed from a low level to a high level. When receiving the active command ACT having the level changed into the high level, the RAS control circuit 1 may change the level of the row active signal RACT from a low level to a high level. After changing the level of the row active signal RACT into the high level, the RAS control circuit 1 may change the level of the sense amplifier enable signal SAEN from a low level to a high level. When receiving the word line precharge command WLPCG having a level changed from a low level to a high level, the RAS control circuit 1 may change the level of the row active signal RACT into a low level. Furthermore, when receiving the bit line precharge command BLPCG having a level changed into a high level, the RAS control circuit 1 may change the level of the sense amplifier enable signal SAEN into a low level.

As a result, when receiving the active command ACT in the state in which the mode enable signal MODE_en has been enabled, the RAS control circuit 1 may sequentially enable the row active signal RACT and the sense amplifier enable signal SAEN. Furthermore, the RAS control circuit 1 may disable the row active signal RACT that has been enabled when receiving the word line precharge command WLPCG, and may disable the sense amplifier enable signal SAEN when receiving the bit line precharge command BLPCG.

The mode enable signal MODE_en may be a signal that is input to the RAS control circuit 1 and that determines whether to simultaneously disable the row active signal RACT and the sense amplifier enable signal SAEN based on the word line precharge signal WLPCG or to disable the row active signal RACT based on the word line precharge signal WLPCG or disable the sense amplifier enable signal SAEN based on the bit line precharge signal BLPCG.

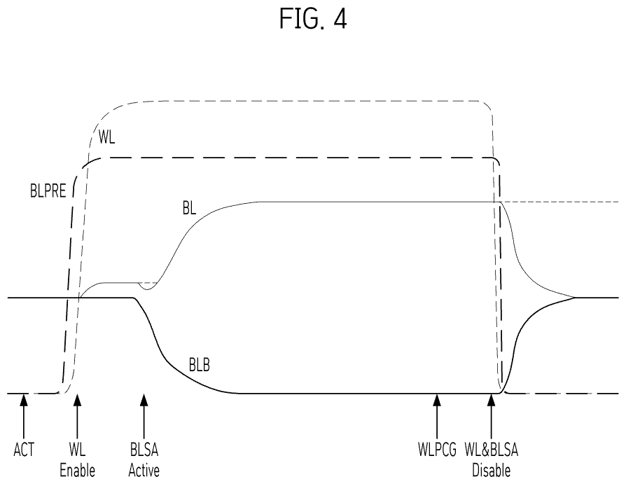

FIG. 4 is a timing diagram for describing an operation of the memory device 200 in the state in which the mode enable signal MODE_en has been disabled as in A) of FIG. 3. In FIG. 4, it is illustrated that the multi-enable signal Multi_en is also in the state in which the multi-enable signal Multi_en has been disabled.

The active command ACT may be received by the memory device 200.

The active command ACT may be received by the RAS control circuit 1.

When receiving the active command ACT, the RAS control circuit 1 may sequentially enable the row active signal RACT and the sense amplifier enable signal SAEN. Furthermore, the RAS control circuit 1 may generate the first mat address MAT_ADDR based on the row address RADD. In this case, the first mat address MAT_ADDR may include information regarding a mat including an enabled word line, among the first to fourth mats MAT0, MAT1, MAT2, and MAT3. That is, the first mat address MAT_ADDR may include information regarding one word line group that is selected among the first to fourth word line groups WL0<0:n>, WL1<0:n>, WL2<0:n>, and WL3<0:n>.

When the active signal RACT and the sense amplifier enable signal SAEN are enabled, the BLSA control circuit 2 may disable one bit line precharge signal BLPRE corresponding to the first mat address MAT_ADDR, among the first to fifth bit line precharge signals BLPRE<0>, BLPRE<1>, BLPRE<2>, BLPRE<3>, and BLPRE<4>. In this case, the bit line precharge signal BLPRE may be disabled to a high level.

When the row active signal RACT is enabled, the row decoder 3 may select one word line group corresponding to the row address RADD, among the first to fourth word line groups WL0<0:n>, WL1<0:n>, WL2<0:n>, and WL3<0:n>, may select one word line WL, among the plurality of word lines included in the selected word line group, and may enable the selected word line.

The word line WL may be enabled, and thus a memory cell (not illustrated) and the positive bit line BL may be electrically connected. When the memory cell and the positive bit line BL are electrically connected, a difference between the voltage levels of the positive bit line BL and the negative bit line BLB may occur due to charges stored in the memory cell. When the bit line precharge signal BLPRE is disabled, a corresponding BLSA may be activated. The activated BLSA may sense and amplify a difference between the voltage levels of the positive bit line BL and the negative bit line BLB.

The above operation may be an operation of the memory device 200, which is performed by the active command ACT until a BLSA amplifies a difference between the voltage levels of the positive bit line BL and the negative bit line BLB.

An operation of the memory device 200, which is performed by the read command RD that is received by the memory device 200 after the active command ACT, is described as follows.

The address selection circuit 9 may provide the first mat address MAT_ADDR to the mat selection circuit 10 because the mode enable signal MODE_en is in the state in which the mode enable signal MODE_en has been disabled.

The mat selection circuit 10 may enable one mat selection signal corresponding to the first mat address MAT_ADDR, among the first to fifth mat selection signals MATS<0>, MATS<1>, MATS<2>, MATS<3>, and MATS<4>. In this case, the mat selection circuit 10 may select and enable the one mat selection signal based on the first mat address MAT_ADDR that has disabled the bit line precharge signal BLPRE. Accordingly, one of the first to fifth LSAs LSA0 to LSA4 that are electrically connected to an activated BLSA may be selected and activated.

The activated LSA may receive the amplified value of the activated BLSA, and may transmit the amplified value to the IOSA 7 by amplifying the amplified value.

The IOSA 7 may output the value received from the activated LSA to the global input and output line GIO as data by amplifying the value. The data that are transmitted to the global input and output line GIO may be transmitted to the controller 100 through the input and output pad.

The above operation may be an operation of the memory device 200, which is performed by the read command RD until data are transmitted from an activated BLSA to the controller 100.

An operation of the memory device 200, which is performed by the word line precharge command WLPCG after the read command RD, is described as follows.

The word line precharge command WLPCG may be received by the memory device 200.

When receiving the word line precharge command WLPCG in the state in which the mode enable signal MODE_en has been disabled, the RAS control circuit 1 may disable both the row active signal RACT and the sense amplifier enable signal SAEN.

When the row active signal RACT is disabled, the row decoder 3 may disable the word line WL disabled by the active command ACT.

Furthermore, when the sense amplifier enable signal SAEN is disabled, the BLSA control circuit 2 may enable the bit line precharge signal BLPRE that has been disabled.

When the bit line precharge signal BLPRE is enabled, a corresponding BLSA may be deactivated, and the positive bit line BL and the negative bit line BLB that have been amplified may be precharged.

As described above, the state in which the mode enable signal MODE_en has been disabled may include the state in which the memory device 200 has been configured to sequentially receive the active command ACT, the read command RD, and the word line precharge command WLPCG and to output data stored in the memory device 200.

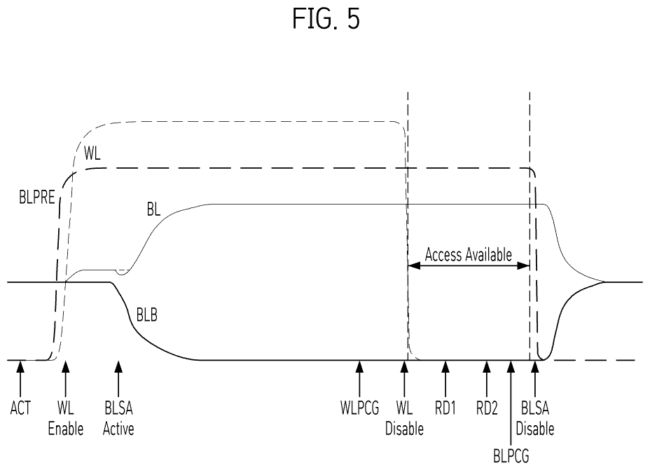

FIG. 5 is a timing diagram for describing an operation of the memory device 200 in the state in which the mode enable signal MODE_en has been enabled as in B) of FIG. 3. In FIG. 5, it is illustrated that the multi-enable signal Multi_en is also in the state in which the multi-enable signal Multi_en has been enabled.

The active command ACT may be continuously received by the memory device 200. For example, as illustrated in FIG. 1, the first active command ACT1 and the second active command ACT2 may be continuously received by the memory device 200.

The first and second active commands ACT1 and ACT2 may be sequentially input to the RAS control circuit 1.

When receiving the first and second active commands ACT1 and ACT2, the RAS control circuit 1 may enable the row active signal RACT and the sense amplifier enable signal SAEN. Furthermore, the RAS control circuit 1 may generate the first mat address MAT_ADDR based on the row address RADD corresponding to each of the first and second active commands ACT1 and ACT2. In this case, the first mat address MAT_ADDR may include information regarding mats including an enabled word line, among the first to fourth mats MAT0, MAT1, MAT2, and MAT3. That is, the first mat address MAT_ADDR may include information regarding a plurality of word line groups selected among the first to fourth word line groups WL0<0:n>, WL1<0:n>, WL2<0:n>, and WL3<0:n>. In this case, the row address RADD corresponding to each of the first and second active commands ACT1 and ACT2 may enable the word lines of mats that are not adjacent to each other. For example, when a word line of the second mat MAT1 is selected by the row address RADD corresponding to the first active command ACT1, the row address RADD corresponding to the second active command ACT2 needs to be received so that a word line of the fourth mat MAT3 is selected. At this time, when the word line of the second mat MAT1 is enabled by the first active command ACT and the row address RADD and the word line of the fourth mat MAT3 is enabled by the second active command ACT2 and the row address RADD, the interval in which the word line of the second mat MAT1 is enabled and the interval in which the word line of the fourth mat MAT3 is enabled may overlap.

When the active signal RACT and the sense amplifier enable signal SAEN are enabled, the BLSA control circuit 2 may disable a plurality of bit line precharge signals BLPRE corresponding to the first mat address MAT_ADDR, among the first to fifth bit line precharge signals BLPRE<0>, BLPRE<1>, BLPRE<2>, BLPRE<3>, and BLPRE<4>. At this time, the bit line precharge signal BLPRE may be disabled to a high level. For example, when a word line of the second mat MAT1 is enabled by the row address RADD of the first active signal ACT1 and a word line of the fourth mat MAT3 is enabled by the row address RADD of the second active signal ACT2, when the active signal RACT and the sense amplifier enable signal SAEN are enabled, the BLSA control circuit 2 may disable the third bit line precharge signal BLPRE<2> and the fifth bit line precharge signal BLPRE<4> based on the first mat address MAT_ADDR.

When the row active signal RACT is enabled, the row decoder 3 may select a plurality of word line groups corresponding to the row address RADD, among the first to fourth word line groups WL0<0:n>, WL1<0:n>, WL2<0:n>, and WL3<0:n>, may select one word line WL, among a plurality of word lines included in the selected word line group, and may enable the selected one word line. For example, when a word line of the second mat MAT1 is enabled by the row address RADD of the first active signal ACT1 and a word line of the fourth mat MAT3 is enabled by the row address RADD of the second active signal ACT2, the row decoder 3 may enable a word line of the second word line group WL1<0:n> and a word line of the fourth word line group WL3<0:n> when the row active signal RACT is enabled.

The word line WL may be enabled, and thus a memory cell (not illustrated) and the positive bit line BL may be electrically connected. When the memory cell and the positive bit line BL are electrically connected, a difference between the voltage levels of the positive bit line BL and the negative bit line BLB may occur due to charges stored in the memory cell. When the bit line precharge signal BLPRE is disabled, a corresponding BLSA may be activated. The activated BLSA may sense and amplify a difference between the voltage levels of the positive bit line BL and the negative bit line BLB. For example, when word lines of the second and fourth word line groups WL1<0:n> and WL3<0:n> are enabled, memory cells that are connected to enabled word lines of the second and fourth mats MAT1 and MAT3 may be electrically connected to the positive bit line BL. A difference between the voltage levels of the positive bit line BL and the negative bit line BLB may occur. Furthermore, each of the third and fifth BLSAs BLSA2 and BLSA4 that are activated by the third and fifth bit line precharge signals BLPRE<2> and BLPRE<4> that have been disabled, respectively, may sense and amplify a difference between the voltage levels of the positive bit line BL and the negative bit line BLB.

The above operation may be an operation of the memory device 200, which is performed by the active command ACT until a BLSA amplifies a difference between the voltage levels of the positive bit line BL and the negative bit line BLB.

After the first and second active commands ACT1 and ACT2, the word line precharge command WLPCG may be received by the memory device 200.

When receiving the word line precharge command WLPCG, the RAS control circuit 1 may disable the row active signal RACT.

The row active signal RACT that has been disabled is received by the row decoder 3. When the row active signal RACT is disabled, the row decoder 3 may disable word lines that have been enabled. For example, the row decoder 3 may disable enabled word lines of the second and fourth word line groups WL1<0:n> and WL3<0:n>.

An operation of the memory device 200, which is performed by the first and second read commands RD1 and RD2 that are received by the memory device 200 after the word line precharge command WLPCG, is described as follows.

The CAS control circuit 8 may sequentially receive the first read command RD1 and the second read command RD2. The CAS control circuit 8 may generate the second mat address MAT_ADDC based on the column address CADD of the first read command RD1 and generate the second mat address MAT_ADDC based on the column address CADD of the second read command RD2 because the mode enable signal MODE_en is in the state in which the mode enable signal MODE_en has been enabled.

Furthermore, the address selection circuit 9 may provide the second mat address MAT_ADDC to the mat selection circuit 10 because the mode enable signal MODE_en is in the state in which the mode enable signal MODE_en has been enabled.

The mat selection circuit 10 may enable one mat selection signal corresponding to the second mat address MAT_ADDC, among the first to fifth mat selection signals MATS<0>, MATS<1>, MATS<2>, MATS<3>, and MATS<4>. After enabling the one mat selection signal corresponding to the second mat address MAT_ADDC that is generated based on the column address CADD of the first read command RD1, the mat selection circuit 10 may enable one mat selection signal corresponding to the second mat address MAT_ADDC that is generated based on the column address CADD of the second read command RD2. For example, after enabling the third mat selection signal MATS<2> based on the second mat address MAT_ADDC that is generated based on the column address CADD of the first read command RD1, the mat selection circuit 10 may enable the fifth mat selection signal MATS<4> based on the second mat address MAT_ADDC that is generated based on the column address CADD of the second read command RD2. In this case, the third and fifth LSAs 6-2 and 6-4 that receive the third and fifth mat selection signals MATS<2> and MATS<4> that have been enabled may be sequentially activated.

The third and fifth LSAs 6-2 and 6-4 that have been sequentially activated may receive the amplified values of the third and fifth BLSA arrays 5-2 and 5-4 that have been activated, respectively, and may sequentially transmit the amplified values to the IOSA 7 by amplifying the amplified values.

The IOSA 7 may output the values that have been sequentially received from the LSAs 6-2 and 6-4 to the global input and output line GIO as data by amplifying the values. The data that have been transmitted to the global input and output line GIO may be transmitted to the controller 100 through the input and output pad.

The above operation may be an operation of the memory device 200, which is performed by a continued read command RD until data are transmitted from BLSAs activated by a continued active command ACT to the controller 100. An interval (illustrated as “Access available” in FIG. 5) in which the BLSAs are deactivated by the bit line precharge command BLPCG after the word line precharge command WLPCG is received and the word lines WL are disabled may be an interval in which the continued read commands RD1 and RD2 may be received.

An operation of the memory device 200, which is performed by the bit line precharge command BLPCG after the continued read commands RD1 and RD2, is described as follows.

The bit line precharge command BLPCG may be received by the memory device 200.

When receiving the bit line precharge command BLPCG in the state in which the mode enable signal MODE_en has been enabled, the RAS control circuit 1 may disable the sense amplifier enable signal SAEN.

When the sense amplifier enable signal SAEN is disabled, the BLSA control circuit 2 may enable the bit line precharge signal BLPRE that has been disabled. For example, when the sense amplifier enable signal SAEN is disabled, the BLSA control circuit 2 may enable the third and fifth bit line precharge signals BLPRE<2> and BLPRE<4> that have been disabled from a high level to a low level.

When the bit line precharge signal BLPRE is enabled, the BLSA may be deactivated, and the positive bit line BL and the negative bit line BLB that have been amplified may be precharged. For example, when the third and fifth bit line precharge signals BLPRE<2> and BLPRE<4> are enabled, each of the third and fifth BLSA arrays 5-2 and 5-4 may be deactivated, and may precharge the positive bit line BL and the negative bit line BLB that have been amplified.

As described above, the state in which the mode enable signal MODE_en has been enabled may include the state in which the memory device 200 is configured to sequentially receive the continued active commands ACT1 and ACT2, the word line precharge command WLPCG, the continued read commands RD1 and RD2, and the bit line precharge command BLPCG and to output data stored in the memory device 200.

Although embodiments according to the technical spirit of the present disclosure have been described above with reference to the accompanying drawings, the embodiments have been provided to merely describe embodiments according to the concept of the present disclosure, and are not limited to the illustrated embodiments. A person having ordinary knowledge in the art to which the present disclosure pertains may substitute, modify, and change the embodiments in various ways without departing from the technical spirit of the present disclosure written in the claims. Such substitutions, modifications, and changes may be said to belong to the scope of the present disclosure. Furthermore, the embodiments may be combined to form additional embodiments.

What is claimed is:

1. An operating method of a memory device, the operating method comprising:
receiving a row address that designates a first word line and an active command;
enabling the first word line and activating a first bit line sense amplifier (BLSA) array corresponding to the first word line;
receiving a row address that designates a second word line and the active command; and
enabling the second word line and activating a second BLSA array corresponding to the second word line.

2. The operating method of claim 1, further comprising:
activating the first BLSA array and receiving a read command for reading data amplified by the activated first BLSA array;
outputting the data amplified by the activated first BLSA array;
activating the second BLSA array and receiving a read command for reading data amplified by the activated second BLSA array; and
outputting the data amplified by the activated second BLSA array.

3. The operating method of claim 1, further comprising:
receiving a word line precharge command after activating the second BLSA array; and
disabling the first word line and the second word line in response to the word line precharge command.

4. The operating method of claim 2, further comprising:
receiving a bit line precharge command after outputting the data amplified by the activated second BLSA array; and
deactivating the first and second BLSA arrays in response to the bit line precharge command.

5. The operating method of claim 2, further comprising:
receiving a bit line precharge command after outputting the data amplified by the activated second BLSA array; and
deactivating the first and second BLSA arrays and disabling the first and second word lines in response to the bit line precharge command.

6. The operating method of claim 2, further comprising:
receiving a word line precharge command after activating the second BLSA array;
disabling the first word line and the second word line in response to the word line precharge command;
receiving a bit line precharge command after outputting the data amplified by the activated second BLSA array; and
deactivating the first and second BLSA arrays in response to the bit line precharge command.

7. The operating method of claim 1, wherein:
an interval in which the first word line is enabled and an interval in which the second word line is enabled overlap, and
the first word line and the second word line belong to an identical bank.

8. A memory device comprising:
a plurality of data storage regions each comprising a plurality of memory cells;
a plurality of bit line sense amplifier (BLSA) arrays configured to sense and amplify data stored in the respective plurality of data storage regions; and
a RAS control circuit configured to disable, in response to a word line precharge command, one or more enabled word lines among a plurality of word lines coupled to the plurality of data storage regions and configured to deactivate, in response to a bit line precharge command, one or more activated BLSA arrays among the plurality of BLSA arrays.

9. The memory device of claim 8, wherein each of the memory cells is electrically connected to the BLSA array through a bit line when a corresponding word line is enabled among the plurality word lines.

10. The memory device of claim 8, wherein the RAS control circuit is configured to:
enable a row active signal and a sense amplifier enable signal when receiving an active command,
disable the row active signal when receiving the word line precharge command,
disable the sense amplifier enable signal when receiving the bit line precharge command, and
generate a first mat address according to a row address.

11. The memory device of claim 10, wherein the first mat address comprises information of a selected data storage region of the plurality of data storage regions, the selected data storage region being coupled to a corresponding word line among the enabled word lines.

12. The memory device of claim 10,
further comprising a row decoder configured to enable selected word lines among the plurality of word lines in response to the row address when the row active signal is enabled and configured to disable the selected word lines when the row active signal is disabled,
wherein the selected word lines are coupled to data storage regions that are not adjacent to each other among the plurality of data storage regions.

13. The memory device of claim 11, further comprising a BLSA control circuit configured to activate one or more BLSA arrays, which correspond to the first mat address among the plurality of BLSA arrays, when the sense amplifier enable signal is enabled, and configured to deactivate the one or more activated BLSA arrays when the sense amplifier enable signal is disabled.

14. The memory device of claim 8, further comprising:
a CAS control circuit configured to generate a second mat address in response to the column address when receiving a read command and a column address; and
a plurality of local sense amplifiers (LSAs) configured to transmit data, which is sensed and amplified by the one or more activated BLSAs, to an input and output sense amplifier (IOSA) in response to the second mat address.

15. A memory device comprising:
a row decoder configured to enable a first word line by receiving a row address that designates the first word line and an active command and enable a second word line by receiving a row address that designates a second word line and the active command; and
a RAS control circuit configured to activate a first bit line sense amplifier (BLSA) corresponding to the first word line based on the row address that designates the first word line and activate a second BLSA corresponding to the second word line based on the row address that designates the second word line.

16. The memory device of claim 15, wherein the row decoder is further configured to disable the enabled first and second word lines based on the word line precharge command.

17. The memory device of claim 15, wherein the RAS control circuit is further configured to deactivate the activated first and second BLSA arrays based on the bit line precharge command.

18. The memory device of claim 15, further comprising
a CAS control circuit configured to transmit first data, which is amplified by the activated first BLSA, to an input and output sense amplifier (IOSA) based on a read command and a column address for the first data and transmit second data, which is amplified by the activated second BLSA, to the IOSA based on a read command and a column address for the second data.

19. The memory device of claim 15, wherein:
the first word line is electrically connected to a first mat comprising a plurality of memory cells within the memory device,
the second word line is electrically connected to a second mat comprising a plurality of memory cells within the memory device, and
the first and second mats are not adjacent to each other.
